(19) United States
(12) Patent Application Publication
(10) Pub. No.: US 2013/0137334 A1
(43) Pub. Date: May 30, 2013

(54) FILM FORMATION APPARATUS, FILM FORMATION METHOD, AND MASK UNIT TO BE USED FOR THEM

(71) Applicant: Canon Kabushiki Kaisha, Tokyo (JP)

(72) Inventor: Nobuyuki Ishikawa, Sanbu-gun (JP)

(73) Assignee: CANON KABUSHIKI KAISHA, Tokyo (JP)

(21) Appl. No.: 13/675,238

(22) Filed: Nov. 13, 2012

(30) Foreign Application Priority Data
Nov. 29, 2011 (JP) 2011-260416

(51) Int. Cl. C23C 16/04; H01L 51/00

(52) U.S. Cl. CPC C23C 16/042; H01L 51/0012
USPC 445/58; 118/720; 427/282; 427/248.1; 118/504

(57) ABSTRACT

Provided is a film formation apparatus for manufacturing an apparatus such as an organic electroluminescence light emitting apparatus, which has high resolution and high productivity. The film formation apparatus includes: multiple mask unit holding portions for supporting mask units, respectively; multiple alignment mechanisms provided in accordance with the multiple mask unit holding portions; and a vapor deposition source in which the multiple mask units are aligned and arranged by the multiple alignment mechanisms one by one with respect to one substrate, and then film formation is performed.

### BACKGROUND OF THE INVENTION

1. Field of the Invention

The present invention relates to a film formation apparatus, a film formation method using the film formation apparatus, and a mask unit to be used in the film formation apparatus and the film formation method.

2. Description of the Related Art

A planar-type display apparatus (organic electroluminescence (EL) display), which is formed by arraying multiple organic EL light emitting elements which are each selectively controlled to emit light of a predetermined wavelength, is now drawing attention.

The organic EL display is generally formed by using a vacuum thin film formation technology. Note that, when the organic EL display is manufactured, it is necessary to array multiple organic EL light emitting elements vertically and laterally in matrix on a substrate such as transparent glass. Therefore, when the organic EL display is manufactured, it is essential to perform fine patterning when the organic EL elements having specific emission colors are formed in predetermined regions. In particular, when the organic EL display for color image display is manufactured, for example, it is necessary to form patterned films corresponding to respective color components of red (R), green (G), and blue (B), thereby selectively forming the organic EL light emitting elements of the respective colors in determined regions.

However, the mask accuracy and the alignment accuracy of positioning between a mask and a substrate tend to degrade as the substrate and the mask increase in size.

Further, in vapor deposition film formation of the vacuum thin film formation technology, as the substrate and the mask increase in size, the deformation of the substrate and the mask tends to increase due to the temperature of a vapor deposition source.

In recent years, various proposals have been made to solve the above-mentioned problems. Japanese Patent Application Laid-Open No. 2003-217850 proposes a method of forming thin films on an entire surface of the substrate with use of a mask in which at least two unit masks are fixed to a frame having an opening portion. Note that, the unit mask disclosed in Japanese Patent Application Laid-Open No. 2003-217850 includes at least one unit masking pattern portion (one mask opening portion) in a longitudinal direction thereof.

However, in the method proposed in Japanese Patent Application Laid-Open No. 2003-217850, the positional accuracy when fixing the individual unit masks to the frame depends on the pattern array accuracy on the entire surface of the substrate. Therefore, as the number of the unit masks becomes larger, necessary mask accuracy cannot be obtained as a whole substrate more frequently, which has been a problem.

### SUMMARY OF THE INVENTION

The present invention has been made to solve the above-mentioned problems, and has an object to provide a film formation apparatus for manufacturing an apparatus such as an organic EL light emitting apparatus, which has high resolution and high productivity.

According to an exemplary embodiment of the present invention, there is provided a film formation apparatus, including: multiple mask unit holding portions for supporting multiple mask units, respectively; multiple alignment mechanisms provided in accordance with the multiple mask unit holding portions; and a vapor deposition source, in which the multiple mask units are aligned and arranged by the multiple alignment mechanisms one by one with respect to one substrate.

Alternatively, according to another exemplary embodiment of the present invention, there is provided a film formation method of forming a patterned film on a substrate, the film formation method including: preparing multiple mask units each including opening pattern units; aligning the multiple mask units one by one with respect to the substrate; and collectively forming films on the substrate via the opening pattern units of the multiple mask units.

Further, according to another exemplary embodiment of the present invention, there is provided a mask unit to be used in the film formation apparatus and the film formation method described above, the mask unit including: a mask member including an opening portion in which multiple opening pattern units are arranged in parallel to each other; and a frame for fixing the mask member, in which the frame includes: two mask member fixing portions each including a surface for fixing the mask member; and a support portion fixed to a surface of each of the two mask member fixing portions on a side opposite to a side on which the mask member is fixed, the support portion supporting the two mask member fixing portions.

According to the present invention, it is possible to provide the film formation apparatus for manufacturing an apparatus such as an organic EL light emitting apparatus, which has high resolution and high productivity.

Further features of the present invention will become apparent from the following description of exemplary embodiments with reference to the attached drawings.

### BRIEF DESCRIPTION OF THE DRAWINGS

FIGS. 1A and 1B are a side view and a perspective view, respectively, of a film formation apparatus according to a first embodiment of the present invention.

FIGS. 2A, 2B, and 2C are schematic sectional views illustrating specific examples of a mask unit used in the film formation apparatus of FIGS. 1A and 1B.

FIGS. 3A and 3B are plan views illustrating a specific example of an arrangement mode of mask units with respect to a substrate, in which FIG. 3A is an entire view of the arrangement mode and FIG. 3B is an enlarged view of an X region of FIG. 3A.

FIG. 4 is a perspective view illustrating an example of a film formation apparatus according to a second embodiment of the present invention.

FIG. 5 is a plan view illustrating another specific example of the arrangement mode of the mask units with respect to the substrate.

### DESCRIPTION OF THE EMBODIMENTS

Preferred embodiments of the present invention will now be described in detail in accordance with the accompanying drawings.

A film formation apparatus of the present invention includes multiple mask unit holding portions and multiple alignment mechanisms. In the film formation apparatus of the present invention, the mask unit holding portion is a member which holds a mask unit including a mask member and a frame for fixing the mask member. Further, in the film formation apparatus of the present invention, the alignment mechanism is provided in accordance with the mask unit holding portion, that is, one alignment mechanism is provided with respect to one mask unit. As described above, in the film formation apparatus of the present invention, alignment is possible for each mask unit. Therefore, as compared to the conventional technology of Japanese Patent Application Laid-Open No. 2003-217850, thin films shaped into a desired pattern can be formed in a highly-accurate state.

The above-mentioned mask member used in the present invention includes an opening portion in which multiple opening pattern units are arranged in parallel to each other. One opening pattern unit corresponds to a film formation pattern necessary for one display region to be manufactured. The multiple opening pattern units are arranged in the mask member in at least one row, and two sides of the mask member, which are perpendicular to the row of the opening portion, are fixed to the mask frame. Further, two sides of the mask member, which are parallel to the row of the opening portion, are not fixed to the mask frame. In the present invention, the number of rows of the opening pattern units which form the opening portion and are arranged in parallel in a certain direction is not particularly limited as long as the number of rows is smaller than the number of rows of the film formation regions (that is, display regions) formed in one substrate to be subjected to film formation (the number of display regions arranged in a long-side direction of the substrate). From the viewpoint of increasing fineness, the number of rows of the opening pattern units is preferred to be as small as possible. It is most preferred that the number of rows of the opening pattern units be one. Further, the number of the opening pattern units provided in the mask member corresponds to the number of columns of the film formation regions (that is, display regions) (the number of display regions arranged in a short-side direction of the substrate). Therefore, the long-side length of the mask member corresponds to the short-side length of the substrate to be subjected to film formation with use of the mask unit.

In the film formation apparatus of the present invention, the multiple mask units are aligned and arranged by the above-mentioned alignment mechanisms one by one with respect to the one substrate in which the multiple display regions are provided in matrix.

Further, the film formation apparatus of the present invention is an apparatus for collectively forming thin films without replacing or moving the mask units during film formation.

The film formation apparatus of the present invention has the above-mentioned configuration, and hence, as compared to a case where the conventional vacuum film formation method using a mask, in particular, a vapor deposition method is used, patterned films can be formed on a large-sized substrate with higher accuracy.

Note that, the frame included in the mask unit of the present invention includes at least two mask member fixing portions each having a surface for fixing the mask member, and a support portion which is fixed to surfaces of the respective mask member fixing portions on a side opposite to the side on which the mask member is fixed, and which supports those mask member fixing portions. The support portion is preferred to be provided at a distance from the mask member so that the substrate may be arranged between the support portion and the mask member during film formation. With such a frame configuration, the mask member can be supported by the frame at only two sides, and hence the multiple mask units can be arranged so that the sides of the mask members, which are not fixed to the frames, are adjacent to each other. In this case, the mask units can be arrayed more finely while preventing the frame from interfering with the frame of the adjacent mask unit.

In the following, embodiments of the present invention are described with reference to the drawings as appropriate. Note that, for the sake of easy understanding of the description, the drawings referred to in the following description may illustrate the whole or part of the member in a scale different from the actual case. Further, the following description is merely an exemplary embodiment of the present invention, and the present invention is not limited to the embodiments described below.

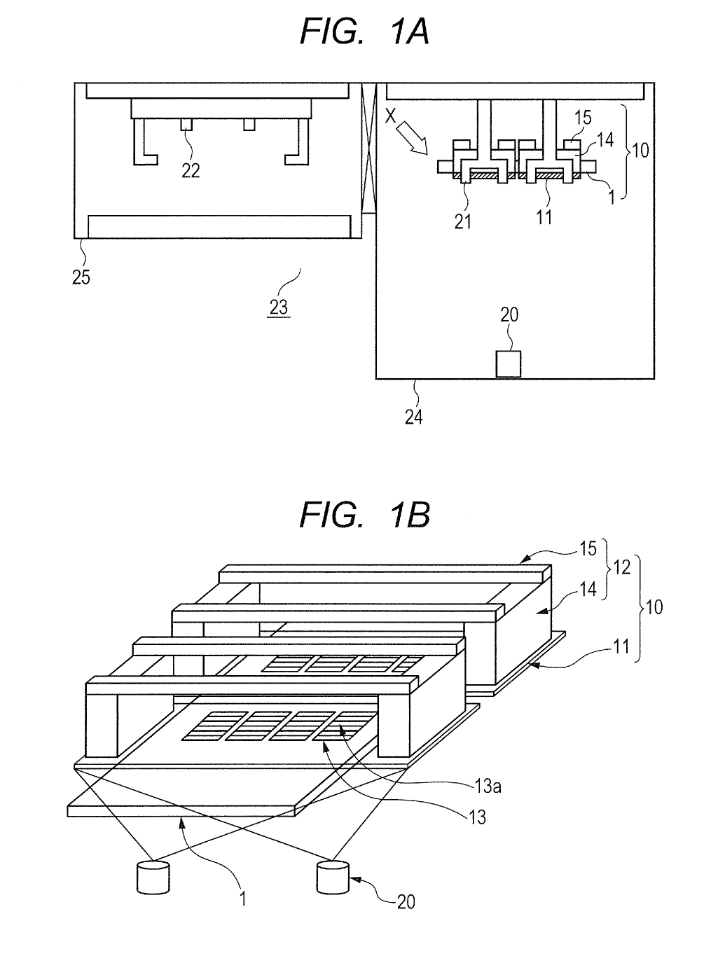

FIG. 1A is a schematic view illustrating a film formation apparatus according to a first embodiment of the present invention, and illustrates a state during film formation. FIG. 1B is a perspective view in the film formation state as viewed from an arrow X illustrated in FIG. 1A. A film formation apparatus 23 of FIG. 1A is an apparatus for forming thin films in a desired pattern on a film formation surface of a substrate 1, and includes an alignment mechanism 22 for aligning each of multiple mask units with respect to the substrate to be subjected to film formation, a mask unit support portion 21 for supporting each of the multiple mask units, and a vapor deposition source 20. In FIG. 1A, an alignment chamber 25 different from a film formation chamber 24 in which the vapor deposition source 20 is arranged is provided, and the alignment mechanism 22 is arranged therein. However, the alignment chamber 25 may be omitted and the alignment mechanism 22 may be arranged in the film formation chamber 24. The alignment mechanism 22 may have a generally-used configuration, and includes a camera, an actuator for moving the mask unit in XYθ directions, and an ascending and descending mechanism for the substrate or the mask unit.

A mask unit 10 suitably used in the film formation apparatus of FIG. 1B is a member including a mask member 11, and a frame 12 for fixing the mask member 11. Note that, in the following drawings, the same reference symbols as those in FIGS. 1A and 1B represent the same members as those in FIGS. 1A and 1B.

The mask member 11 included in the mask unit 10 is a member formed of a strip-like metal thin film, and includes an opening portion 13 in which multiple opening pattern units 13a are arranged in parallel to each other. Note that, the regions in which the opening pattern units 13a are provided correspond to, among film formation regions 2 provided on the substrate 1 in matrix, film formation regions arrayed in a specific row.

The constituent material of the mask member 11 may be selected as appropriate depending on a method of forming the opening portion 13.

Examples of the method of forming the opening portion 13 include a process method using electroforming. With use of this process method, the process accuracy of the opening portion 13 can be improved. In the case where the opening portion 13 is formed by electroforming, the mask member 11 is made of a metal material such as Cr and Ni.

Alternatively, the opening portion 13 may be formed with use of an etching process. When the opening portion 13 is formed by etching, the mask member 11 may be made of a metal having a small coefficient of thermal expansion, such as invar and super invar. The metal having a small coefficient of thermal expansion is preferred to be used because it is possible to prevent the mask member from expanding due to heat received during film formation. However, the method of forming the opening portion 13 is not limited to those methods.

Further, the frame 12 included in the mask unit includes two mask member fixing portions 14 joined to the mask member 11, and two support portions 15 supporting the mask member fixing portions 14. In the mask unit 10 of FIG. 1B, the mask member fixing portions 14 are joined one by one to two short-side edge portions of the strip-like mask member 11. Further, each of the mask member fixing portions 14 is fixed by the two support portions 15. In this case, the frame 12 illustrated in FIG. 1B has a rigidity as a frame owing to the two support portions 15.

By the way, as illustrated in FIG. 1B, in a state during film formation, the mask member 11 forming the mask unit 10 is located between the vapor deposition source 20 and the substrate 1. On the other hand, the support portions 15 of the frame 12 forming the mask unit 10 are located on a side opposite to the vapor deposition source 20 with respect to the substrate 1.

In order to improve the film formation accuracy of the mask unit 10, the rigidity of the frame 12 is necessary to some extent. On the other hand, the film formation apparatus of the present invention uses the multiple mask units 10, and performs collective film formation for the film formation regions 2 provided in matrix on the one substrate 1. Therefore, multiple frames 12 corresponding to the number of the mask units 10 are necessary. Therefore, the frame 12 forming the mask unit 10 is preferred to have a configuration that does not affect the thin film formation. For example, as illustrated in FIG. 1A, when the support portions 15 of the frame 12 are provided on a side opposite to the vapor deposition source 20 across the substrate 1, the frame 12 does not hinder the film formation, and hence this configuration is preferred.

Note that, the width of the mask member fixing portion 14 forming the frame 12 is not particularly limited as long as adjacent two mask units do not interfere with each other. It is preferred that the width be smaller than the short side of the mask member 11 because the setting interval between the mask units 10 can be narrowed.

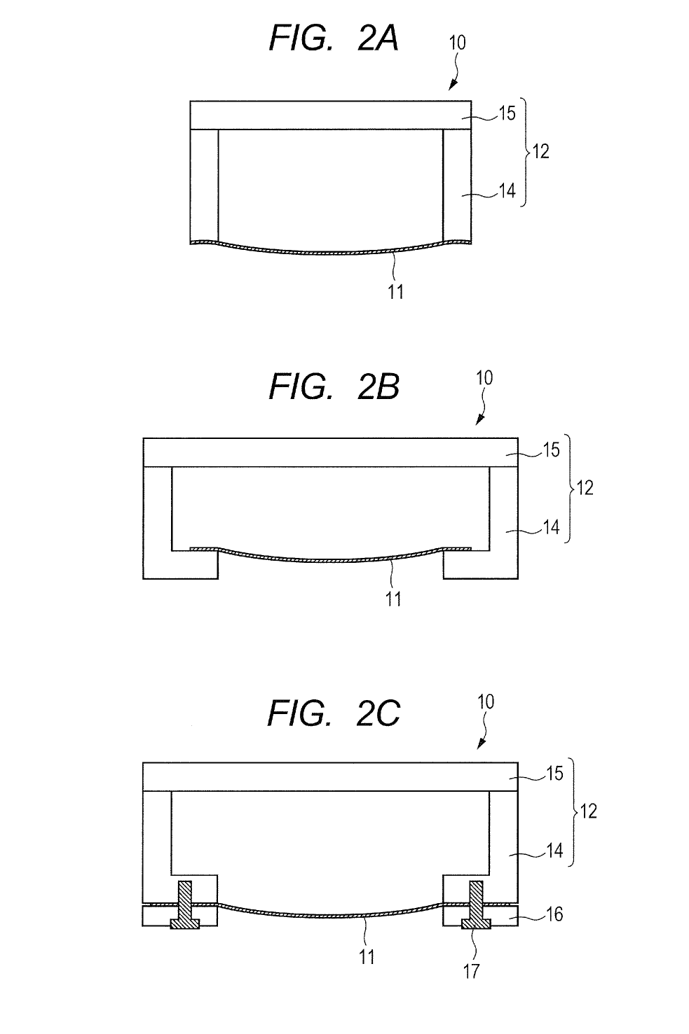

FIGS. 2A to 2C are schematic sectional views illustrating specific examples of the mask unit. Examples of the sectional shape of the mask member fixing portion 14, which forms the mask unit 10 and is joined to the mask member 11, include an I-section type structure illustrated in FIG. 2A and an L-section type structure illustrated in FIGS. 2B and 2C. Note that, the sectional shape of the mask member fixing portion 14 is not particularly limited as long as the mask member 11 can be fixed by the mask member fixing portions 14. In a case where the sectional shape of the mask member fixing portion 14 is an I-section type structure illustrated in FIG. 2A, the mask member 11 is joined to bottom surfaces of the respective mask member fixing portions 14. On the other hand, in a case where the sectional shape of the mask member fixing portion 14 is an L-section type structure illustrated in FIGS. 2B and 2C, the mask member 11 is joined to eave portions of the respective mask member fixing portions 14 illustrated in FIG. 2B or bottom surfaces of the respective mask member fixing portions 14 illustrated in FIG. 2C.

A generally-used method of fixing the mask member 11 to the mask member fixing portions 14 in FIGS. 2A to 2C is, but not limited to, spot welding. Further, when fixing strength is necessary, for example, as illustrated in FIG. 2C, a doubling plate 16 may be mounted to the mask member fixing portions 14 from the mask member 11 side after the spot welding and be fixed by bolts 17.

The frame 12 including the mask member fixing portions 14 and the support portions 15 may be made of a metal material such as SUS and aluminum. When a metal having a small coefficient of thermal expansion is used, thermal stability improves and highly-accurate patterning becomes possible, which is preferred. For example, invar and super invar may be used.

Note that, as illustrated in FIGS. 2A to 2C, when the frame 12 is provided on the side opposite to the vapor deposition source 20 across the substrate 1, the mask units can be arrayed more finely, which is preferred.

By the way, in the film formation apparatus of FIGS. 1A and 1B, two mask units 10 are used with respect to one substrate 1, but the number of the mask units 10 to be used in the film formation apparatus of the present invention is not limited thereto. Note that, a particularly preferred mode is a case where thin films having a desired pattern are formed on a substrate in which display regions (film formation regions) of m rows and n columns are provided with use of mask units each including a mask member in which multiple opening pattern units are arranged in parallel in one row. The mask units are arranged by the number of rows (m) of the display regions. Note that, in this case, the number of the opening pattern units included in the mask member is n, which corresponds to the number of columns of the display regions.

The film formation apparatus of the present invention includes one alignment mechanism with respect to one mask unit. Therefore, the multiple mask units used during film formation can be aligned independently with respect to the substrate. As described above, the film formation apparatus of the present invention can align each mask unit independently, and hence thin films shaped into a desired pattern can be formed in a highly-accurate state. In this case, when the mask units are aligned, it is necessary to prevent the mask units to be used from interfering with each other. Note that, the phrase “prevent interfering” used herein means that the adjacent mask units are not brought into contact with each other.

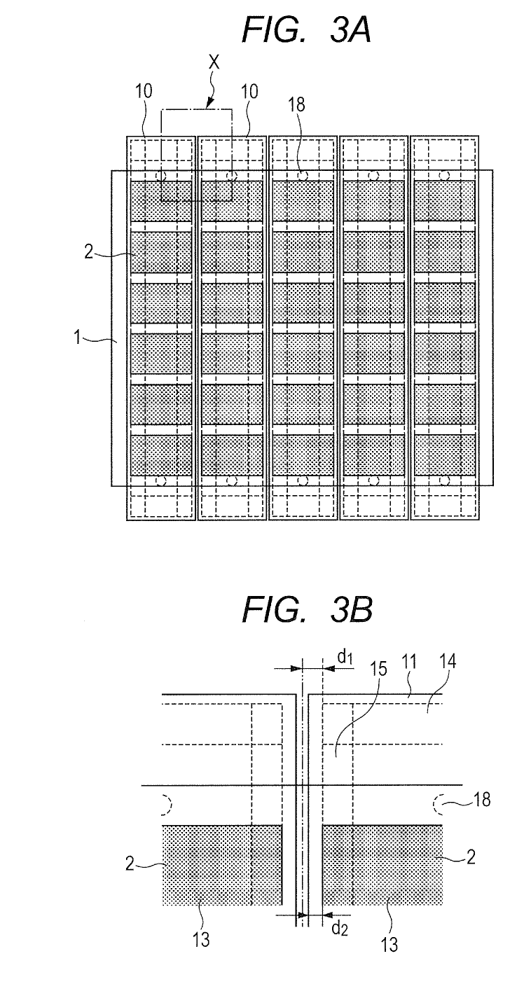

FIGS. 3A and 3B are plan views illustrating a specific example of an arrangement mode of the mask units with respect to the substrate. FIG. 3A is an entire view of the arrangement mode and FIG. 3B is an enlarged view of an X region of FIG. 3A. Note that, the mask unit arranged in FIGS. 3A and 3B is the same as the mask unit illustrated in FIGS. 1A and 1B.

The multiple prepared mask units 10 are each arranged, for example, in a row direction as illustrated in FIG. 3A by the alignment mechanism (not shown). In this case, when the mask unit 10 is arranged, the alignment mechanism is operated for positional alignment so that, for example, an alignment mark 18 of the mask member 11 and an alignment mark (not shown) of the substrate 1 match with each other. Note that, the alignment mark 18 of the mask member 11 is provided in a region in which the mask member 11 and the frame 12 are joined to each other, for example, at each of both end portions in the long-side direction of the strip-like mask member 11 illustrated in FIGS. 1A and 1B or a position at a certain distance from each of both the end portions.

Further, when the mask units 10 are arranged, it is preferred that d₁ and d₂ be appropriately set, where d₁ represents a half of an interval between the film formation regions 2 provided, on the substrate 1, adjacent to each other in a column direction (direction perpendicular to the side of the mask member on which the frame is not fixed), and d₂ represents a distance between an end portion of the opening portion 13 and an end portion of the mask member 11 in the column direction. Specifically, d₁≧d₂ is preferred. With this, it is possible to prevent the mask members 11 respectively included in the adjacent mask units 10 from interfering with each other.

Further, when the mask units 10 are arranged as illustrated in FIG. 3A, the multiple mask units 10 are arranged in contact with each other on the one substrate 1. Therefore, the film formation can be collectively performed with respect to the multiple display regions formed on the substrate 1.

As a method of forming, after the mask units 10 are set, thin films shaped into a desired pattern on the substrate 1, for example, a vapor deposition method is adopted. In order to form the thin films by adopting the vapor deposition method, there are proposed various specific methods in consideration of film thickness uniformity, material use efficiency, and productivity. In particular, for example, as illustrated in FIG. 1B, the present invention may include, but not limited to, two point vapor deposition sources (vapor deposition sources 20) to employ a parallel shot system in which the vapor deposition sources are moved. With this, thin films with a uniform thickness can be formed.

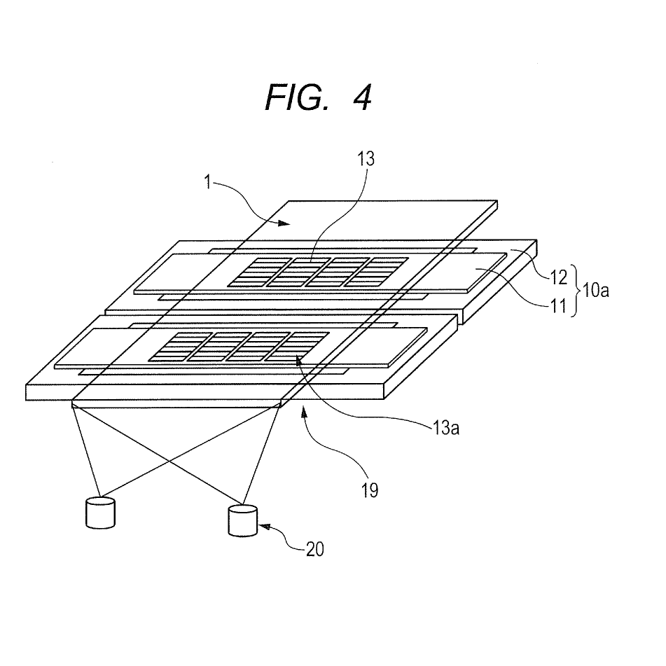

FIG. 4 is a perspective view illustrating an example of a mask unit suitably used in a film formation apparatus according to another embodiment of the present invention. A mask unit 10a of FIG. 4 is different from the mask unit 10 illustrated in FIG. 1B in arrangement relationship between the mask member 11 and the frame 12. Specifically, the mask member 11 is fixed on the frame 12 having an opening portion so that the short-side edge portions of the mask member 11 are joined to the frame 12. Also in the mask unit 10a of FIG. 4, similarly to the film formation apparatus of FIGS. 1A and 1B, the substrate 1 is placed on the mask member 11 for film formation. Therefore, the frame 12 forming the mask unit included in the film formation apparatus of FIG. 4 is arranged on the same side as the vapor deposition source with respect to the substrate 1.

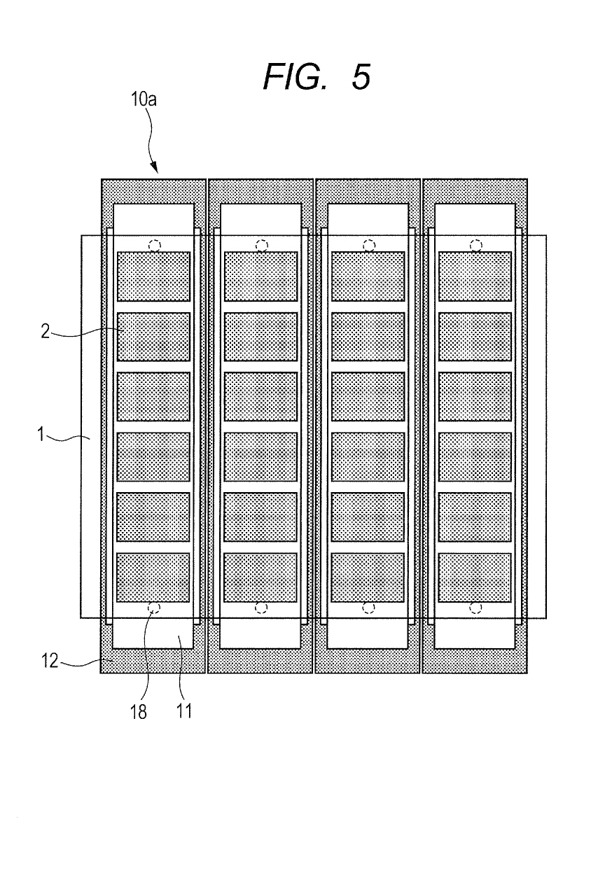

In this case, as illustrated in FIG. 5, multiple mask units 10a are included in the film formation apparatus of FIG. 4, and are arrayed on one substrate 1. When the mask units 10a are arrayed, positional alignment is performed so that the alignment mark 18 provided at a predetermined position of the mask member 11 and the alignment mark (not shown) provided at the predetermined position of the substrate 1 match with each other. As illustrated in FIG. 5, the alignment mark 18 of the mask member 11 is provided, for example, at a position at a certain distance from a region in which the mask member 11 and the frame 12 are joined to each other. For example, the alignment mark 18 of the mask member 11 is provided at each of both end portions in the longitudinal direction of the strip-like mask member 11 illustrated in FIG. 5 or a position at a certain distance from each of both the end portions.

In the case of the configuration of the mask unit 10a, when the multiple mask units are arranged with respect to the substrate, there is a possibility that the frames 12 interfere with each other between the adjacent mask units. Therefore, a distance between the display regions provided on the substrate needs to be taken larger than the case of the mask unit 10. However, film formation is performed under a state in which the multiple mask units are aligned one by one with respect to the one substrate, and hence film formation can be performed with a highly-accurate pattern.

Note that, the mode illustrated in FIG. 5 is merely one specific example, and the present invention is not limited to this mode.

In the following, the present invention is described by way of examples. Note that, the present invention is not limited to the examples.

### EXAMPLE 1

(1) Substrate

First, in a glass substrate having a size of ¼ of the size of the fourth generation glass substrate, circuits including TFTs were formed, to thereby manufacture a TFT substrate (substrate 1). Note that, in the manufactured circuit substrate, display regions for 3.5-inch panels of 326 ppi were arranged in 4 rows vertically and 6 columns horizontally to obtain 24 display regions in total, and one set of circuits for driving the display region was provided to each of the display regions.

(2) Step of Forming Organic EL Elements

Next, on the TFT substrate (substrate 1) thus prepared, organic EL elements of three colors of red, green, and blue (RGB) were formed by a method described below.

First, hole transport layers (HTL), which were layers common to all of the organic EL elements, were formed with use of a vapor deposition mask having openings each sized to correspond to one display region.

Next, R emission layers (R-EML) were formed with use of the film formation apparatus illustrated in FIG. 4. Note that, in this example, as illustrated in FIG. 5, four mask units 10a each including the mask member 11 including six opening pattern units arrayed and arranged in parallel in one row were used, and each alignment mark of the mask unit was overlapped with each alignment mark of the substrate 1. With this, the four mask units 10a were set so as to align in the column direction of the display regions 2. At this time, the slit opening (opening portion 13) of each mask unit 10a was parallel to the short side of the rectangular emission region. Further, in the mask unit 10a used in this example, as the mask member 11, an invar thin plate having a thickness of 40 μm and good thermal stability was used. Further, in the mask unit 10a used in this example, the frame 12 had a lateral length which was equal to or smaller than a long-side pitch of the film formation regions so that the mask units 10a did not interfere with each other during alignment and film formation. With this, adjacent mask units 10a did not overlap with each other when the mask units 10a were arrayed. Further, there was a gap with a certain width between adjacent mask units, and hence even when unnecessary films (materials) adhered to the substrate 1, the unnecessary films (materials) were removed together with the substrate when the substrate 1 was cut for each display region 2.

The mask units 10a were set as described above, and after the TFT substrate (substrate 1) was placed on the four mask units 10a, the R emission layers were formed by collective vapor deposition.

Next, mask units each including an opening portion in formation regions for G emission layers (G-EML) were used, to thereby form the G emission layers by the method similar to the case of forming the R emission layers. Next, mask units each including an opening portion in formation regions for B emission layers (B-EML) were used, to thereby form the B emission layers by the method similar to the case of forming the R emission layers.

After the three types of emission layers (R emission layers, G emission layers, and B emission layers) were formed, electron transport layers (ETL) and electron injection layers, which were layers common to all of the organic EL elements, were formed in the stated order. Next, a film made of indium zinc oxide was formed by a sputtering film formation method, to thereby form a thin film that became a cathode.

Finally, with use of a CVD film formation method, a sealing film formed of a SiN film was formed. Then, the substrate 1 was cut for each display region to obtain an organic light emitting apparatus.

Note that, in this example, it was possible to perform film formation while reducing the use amount of materials to half the use amount in vapor deposition performed in conventional steps.

### EXAMPLE 2

(1) Substrate

First, in a glass substrate having a size of ¼ of the size of the fourth generation glass substrate, circuits including TFTs were formed, to thereby manufacture a TFT substrate (substrate 1). Note that, in the manufactured TFT substrate, display regions for 3.5-inch panels of 326 ppi were arranged in 5 rows vertically and 6 columns horizontally to obtain 30 display regions in total, and one set of circuits for driving the display region was provided to each of the display regions.

(2) Step of Forming Organic EL Elements

Next, on the TFT substrate (substrate 1) thus prepared, organic EL elements of three colors of red, green, and blue (RGB) were formed by a method described below.

First, hole transport layers (HTL), which were layers common to all of the organic EL elements, were formed with use of a vapor deposition mask having openings each sized to correspond to one display region.

Next, R emission layers (R-EML) were formed with use of the film formation apparatus illustrated in FIGS. 1A and 1B. Note that, in this example, as illustrated in FIGS. 3A and 3B, five mask units 10 each including the mask member 11 including six opening pattern units arrayed and arranged in parallel in one row were used, and each alignment mark of the mask unit was overlapped with each alignment mark of the substrate 1. With this, the five mask units 10 were set so as to align in the column direction of the display regions 2. At this time, the slit opening (opening portion 13) of each mask unit 10 was parallel to the short side of the rectangular emission region. Further, in the mask unit 10 used in this example, as the mask member 11, an invar thin plate having a thickness of 40 μm and good thermal stability was used. The mask member 11 was fixed to the frame 12 provided on the side opposite to the vapor deposition source 20 across the substrate 1. More specifically, the mask member 11 was fixed to be joined to the mask member fixing portions 14 forming the frame 12. In this example, the frame 12 had a lateral length which was equal to or smaller than the long-side pitch of the film formation regions so that the mask units 10 did not interfere with each other during alignment and film formation. With this, adjacent mask units 10 did not overlap with each other when the mask units 10 were arrayed.

The mask units 10 were set as described above, and after the TFT substrate (substrate 1) was placed on the five mask units 10, the R emission layers were formed by collective vapor deposition.

Next, mask units each including an opening portion in formation regions for G emission layers (G-EML) were used, to thereby form the G emission layers by the method similar to the case of forming the R emission layers. Next, mask units each including an opening portion in formation regions for B emission layers (B-EML) were used, to thereby form the B emission layers by the method similar to the case of forming the R emission layers.

After the three types of emission layers (R emission layers, G emission layers, and B emission layers) were formed, electron transport layers (ETL) and electron injection layers, which were layers common to all of the organic EL elements, were formed in the stated order. Next, a film made of indium zinc oxide was formed by a sputtering film formation method, to thereby form a thin film that became a cathode.

Finally, with use of a CVD film formation method, a sealing film formed of a SiN film was formed. Then, the substrate 1 was cut for each display region to obtain an organic light emitting apparatus.

Note that, twenty-four (4×6) display regions were taken in Example 1, while thirty (5×6) display regions were taken in this example because the margin was eliminated by closing the units and minimizing the cut margin. As a result, it was possible to realize 1.25-time increase of the number of display regions. As a result, the production efficiency increased by 25% as compared to Example 1.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-260416, filed Nov. 29, 2011, which is hereby incorporated by reference herein in its entirety.

What is claimed is:

1. A film formation apparatus, comprising:
multiple mask unit holding portions for supporting multiple mask units, respectively;
multiple alignment mechanisms provided in accordance with the multiple mask unit holding portions; and
a vapor deposition source,
wherein the multiple mask units are aligned and arranged by the multiple alignment mechanisms one by one with respect to one substrate.

2. The film formation apparatus according to claim 1, further comprising a film formation chamber and an alignment chamber,
wherein the vapor deposition source is provided in the film formation chamber, and
wherein the multiple alignment mechanisms are provided in the alignment chamber.

3. A mask unit to be used in the film formation apparatus according to claim 1, the mask unit comprising:
a mask member comprising an opening portion in which multiple opening pattern units are arranged in parallel to each other; and
a frame for fixing the mask member,
wherein the frame comprises:
two mask member fixing portions each including a surface for fixing the mask member; and
a support portion fixed to a surface of each of the two mask member fixing portions on a side opposite to a side on which the mask member is fixed, the support portion supporting the two mask member fixing portions.

4. The mask unit according to claim 3, wherein the mask member comprises the multiple opening pattern units provided in a row.

5. The mask unit according to claim 3, wherein the mask member has a long-side length which corresponds to a short-side length of a substrate to be subjected to film formation with use of the mask unit.

6. The mask unit according to claim 3, wherein the mask member comprises alignment marks at one of both end portions in a long-side direction of the mask member or a position at a certain distance from both the end portions.

7. A film formation method of forming a patterned film on a substrate, the film formation method comprising:
preparing multiple mask units each including opening pattern units;
aligning the multiple mask units one by one with respect to the substrate; and
collectively forming films on the substrate via the opening pattern units of the multiple mask units.

8. The film formation method according to claim 7, wherein the film formation method uses the film formation apparatus according to claim 1 and the mask unit according to claim 3.

9. The film formation method according to claim 8, wherein the aligning comprises arranging the substrate between the mask member and the support portion.

10. A method of manufacturing an organic electroluminescence display apparatus, the method comprising:
preparing a substrate including a circuit; and
forming an emission layer on the substrate,
wherein the forming an emission layer is carried out by the film formation method according to claim 7.

11. The method of manufacturing an organic electroluminescence display apparatus according to claim 10, wherein the forming an emission layer is carried out with use of the film formation apparatus according to claim 1.

12. The method of manufacturing an organic electroluminescence display apparatus according to claim 10, wherein the forming an emission layer is carried out with use of the mask unit according to claim 3.
